(19) United States
(12) Patent Application Publication
(10) Pub. No.: US 2025/0031512 A1
(43) Pub. Date: Jan. 23, 2025

(54) PHOTOELECTRIC CONVERSION ELEMENT AND IMAGING DEVICE

(71) Applicant: Panasonic Intellectual Property Management Co., Ltd., Osaka (JP)

(72) Inventors: MORIO MITSUISHI, Kanagawa (JP); YASUO MIYAKE, Osaka (JP)

(21) Appl. No.: 18/906,209

(22) Filed: Oct. 4, 2024

Related U.S. Application Data
(63) Continuation of application No. PCT/JP2023/013659, filed on Mar. 31, 2023.

(30) Foreign Application Priority Data
Apr. 21, 2022 (JP) 2022-070203

(51) Int. Cl. H10K 39/32

(52) U.S. Cl. CPC H10K 39/32

(57) ABSTRACT

A photoelectric conversion element includes: a photoelectric conversion layer converting light into signal charge, a first electrode collecting the signal charge, a second electrode, and a first charge blocking layer. The first charge blocking layer blocks charge of polarity opposite to the signal charge. A photocurrent characteristic of the element, with respect to a voltage applied between the first and second electrodes when the photoelectric conversion layer is irradiated with light, exhibits first and second voltage ranges. A photocurrent density at a first voltage in the first voltage range is less than that at a second voltage in the second voltage range. The first voltage is less than the second voltage. A change ratio of photocurrent density at the first voltage is less than that at the second voltage. An absolute value of a difference between the maximum and minimum voltages of the first voltage range is ≥0.5 V.

### BACKGROUND

### 1. Technical Field

The present disclosure relates to a photoelectric conversion element and an imaging device.

### 2. Description of the Related Art

A multilayer imaging device has been proposed as an imaging device of a metal oxide semiconductor (MOS) type. In the multilayer imaging device, a photoelectric conversion element including a photoelectric conversion layer is stacked on a semiconductor substrate, and the charge generated by photoelectric conversion within the photoelectric conversion layer is accumulated in a charge accumulation region. The imaging device reads out its accumulated charge using a charge coupled device (CCD) circuit or a complementary MOS (CMOS) circuit within the semiconductor substrate. For example, Japanese Unexamined Patent Application Publication No. 2009-164604 discloses such an imaging device.

Imaging devices are used in various environments. For example, imaging devices for monitoring or in-vehicle use are required to capture images at high quality even in image capturing environments with large brightness differences.

Hitherto, it has been performed to adjust the luminance values of images output from imaging devices. The luminance values are adjusted according to, for example, the illuminance of the subject. The luminance values can be adjusted, for example, by adjusting the amount of incident light on photoelectric conversion elements provided in the imaging devices. The amount of incident light can be adjusted by various methods, such as adjusting the aperture of the lens, adjusting the exposure time using the shutter, or reducing the light with a neutral density (ND) filter.

In response to such demands, for example, Japanese Unexamined Patent Application Publication No. 2019-176463 discloses a method for controlling the luminance values of images through sensitivity adjustment by changing the voltage applied to the photoelectric conversion element.

### SUMMARY

One non-limiting and exemplary embodiment provides a photoelectric conversion element and an imaging device that, when imaging with adjusted sensitivity, can suppress the degradation of linearity characteristics of the output with respect to the amount of incident light, while also maintaining a sufficient saturated signal amount, even in low-sensitivity imaging.

In one general aspect, the techniques disclosed here feature a photoelectric conversion element including: a photoelectric conversion layer that converts light into signal charge; a first electrode that collects the signal charge; a second electrode; and a first charge blocking layer, located between the photoelectric conversion layer and the second electrode, containing a first charge blocking material, wherein the second electrode is located between the photoelectric conversion layer and the first electrode; the first charge blocking layer is configured to block charge of polarity opposite to that of the signal charge; a photocurrent characteristic of the photoelectric conversion element, with respect to a voltage applied between the first electrode and the second electrode in a case where the photoelectric conversion layer is irradiated with light having certain illuminance, exhibits a first voltage range and a second voltage range; a first photocurrent density at a first voltage included in the first voltage range is less than a second photocurrent density at a second voltage included in the second voltage range; the first voltage is less than the second voltage; a ratio of change in photocurrent density at the first voltage is less than a ratio of change in photocurrent density at the second voltage; and an absolute value of a difference between a maximum voltage of the first voltage range and a minimum voltage of the first voltage range is greater than or equal to 0.5 V.

According to the present disclosure, when imaging with adjusted sensitivity, the degradation of linearity characteristics of the output with respect to the amount of incident light can be suppressed, while a sufficient saturated signal amount can also be maintained, even in low-sensitivity imaging.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic cross-sectional view illustrating the configuration of a photoelectric conversion element according to an embodiment;

FIG. 2 is an exemplary energy band diagram of the photoelectric conversion element according to the embodiment;

FIG. 3 is an energy band diagram in the case where a low voltage is applied between an upper electrode and a lower electrode in the photoelectric conversion element having the energy band configuration illustrated in FIG. 2;

FIG. 4 is an energy band diagram in the case where a high voltage is applied between the upper electrode and the lower electrode in the photoelectric conversion element having the energy band configuration illustrated in FIG. 2;

FIG. 5 is a diagram illustrating an example of the schematic current-voltage characteristics of the photoelectric conversion element according to the embodiment;

FIG. 6 is a diagram illustrating an example of the schematic current-voltage characteristics of a conventional photoelectric conversion element;

FIG. 7 is a diagram illustrating an example of the circuit configuration of an imaging device according to the embodiment;

FIG. 8 is a schematic cross-sectional view illustrating an example of the device structure of a pixel in the imaging device according to the embodiment;

FIG. 9 is an exemplary energy band diagram of another photoelectric conversion element according to the embodiment;

FIG. 10 is a diagram illustrating a portion of a schematic circuit configuration of the pixel according to the embodiment;

FIG. 11 is a diagram illustrating the current-voltage characteristics of a photoelectric conversion element according to a first comparative example;

FIG. 12 is a diagram illustrating the current-voltage characteristics of a photoelectric conversion element according to a first example; and

FIG. 13 is another diagram illustrating the current-voltage characteristics of the photoelectric conversion element according to the first example.

### DETAILED DESCRIPTIONS

### Underlying Knowledge Forming Basis of One Aspect of the Present Disclosure

The inventors have discovered that the following issues arise when adjusting sensitivity by applying voltage to a photoelectric conversion element in order to adjust the luminance values of images output from an imaging device.

Generally, as the voltage applied to the photoelectric conversion element is increased, the photocurrent increases sharply immediately after the voltage begins to rise from 0 V. Therefore, when imaging with reduced sensitivity as an imaging device, it is necessary to set the voltage applied to the photoelectric conversion element to a value around 0 V. In this case, because signal charge that is greater than or equal to the voltage applied to the photoelectric conversion element cannot be accumulated in a charge accumulation region, a sufficient saturated charge amount cannot be maintained.

Additionally, because photocurrent changes sharply with changes in bias voltage, sensitivity in imaging at low sensitivity is more susceptible to changes in electric field intensity due to charge accumulation (changes in the voltage applied to the photoelectric conversion element). That is, in low-sensitivity imaging, sensitivity decreases sharply when signal charge is accumulated in the charge accumulation region, which may easily degrade the linearity characteristics of the output with respect to the amount of incident light.

The present disclosure is based on such knowledge, and provides a photoelectric conversion element and an imaging device that, when imaging with adjusted sensitivity, can suppress the degradation of linearity characteristics of the output with respect to the amount of incident light, while also maintaining a sufficient saturated signal amount, even in low-sensitivity imaging.

An overview of one aspect of the present disclosure is as follows.

A photoelectric conversion element according to one aspect of the present disclosure includes: a photoelectric conversion layer that converts light into signal charge; a first electrode that collects the signal charge; a second electrode; and a first charge blocking layer, located between the photoelectric conversion layer and the second electrode, containing a first charge blocking material, wherein the second electrode is located between the photoelectric conversion layer and the first electrode; the first charge blocking layer is configured to block charge of polarity opposite to that of the signal charge; a photocurrent characteristic of the photoelectric conversion element, with respect to a voltage applied between the first electrode and the second electrode in a case where the photoelectric conversion layer is irradiated with light having certain illuminance, exhibits a first voltage range and a second voltage range; a first photocurrent density at a first voltage included in the first voltage range is less than a second photocurrent density at a second voltage included in the second voltage range; the first voltage is less than the second voltage; a ratio of change in photocurrent density at the first voltage is less than a ratio of change in photocurrent density at the second voltage; and an absolute value of a difference between a maximum voltage of the first voltage range and a minimum voltage of the first voltage range is greater than or equal to 0.5 V.

According to the configuration of this aspect, when imaging with adjusted sensitivity, the degradation of linearity characteristics of the output with respect to the amount of incident light can be suppressed, while a sufficient saturated signal amount can also be maintained, even in low-sensitivity imaging.

Specifically, charge of polarity opposite to that of the signal charge, generated by photoelectric conversion in the photoelectric conversion layer, are hopping-conducted within the photoelectric conversion layer and extracted to the second electrode. At that time, since the first charge blocking layer is located between the photoelectric conversion layer and the second electrode, charge of polarity opposite to that of the signal charge are accumulated at the interface between the photoelectric conversion layer and the first charge blocking layer. Such accumulation of charge at the interface between the photoelectric conversion layer and the first charge blocking layer relaxes (reduces) the electric field intensity on the photoelectric conversion layer. This relaxation of the electric field intensity occurs prominently when a low voltage within the first voltage range is applied to the photoelectric conversion element, leading to lower sensitivity compared to the case where there is no first charge blocking layer. In contrast, when a high voltage greater than or equal to the second voltage range is applied to the photoelectric conversion element, charge of polarity opposite to that of the signal charge have energy sufficient to tunnel through the first charge blocking layer. As a result, it becomes difficult for charge to accumulate at the interface between the photoelectric conversion layer and the first charge blocking layer, thus reducing the effect of electric field relaxation. Accordingly, the sensitivity increases significantly. Using this phenomenon makes it possible to perform low-sensitivity imaging using voltages within the first voltage range as well as high-sensitivity imaging using voltages within the second voltage range or higher. Additionally, because the ratio of change in photocurrent density with respect to voltage in the first voltage range is less than the ratio of change in photocurrent density with respect to voltage in the second voltage range, even in low-sensitivity imaging, when the potential of the first electrode fluctuates due to the collection of the signal charge, the influence of the potential fluctuation on the current density is small, and the degradation of linearity characteristics of the output with respect to the amount of incident light can be suppressed. Furthermore, because the width of the first voltage range is greater than or equal to 0.5 V, a sufficient saturated charge amount can be maintained while coping with the fluctuation of the potential of the first electrode due to the collection of the signal charge.

Additionally, for example, the photoelectric conversion layer contains a donor material and an acceptor material, with the signal charge being holes. The electron affinity of the first charge blocking material may be at least 1 eV less than the electron affinity of the acceptor material.

This makes it easier for electrons, which are charge of polarity opposite to that of holes, to be accumulated at the interface between the photoelectric conversion layer and the first charge blocking layer, making the first voltage range wider.

Alternatively, for example, the photoelectric conversion layer contains a donor material and an acceptor material, with the signal charge being electrons. The ionization potential of the first charge blocking material may be at least 1 eV greater than the ionization potential of the donor material.

This makes it easier for holes, which are charge of polarity opposite to that of electrons, to be accumulated at the interface between the photoelectric conversion layer and the first charge blocking layer, making the first voltage range wider.

Additionally, for example, in the photocurrent characteristic, a maximum value of the photocurrent density in the first voltage range may be less than or equal to 10% of a maximum value of the photocurrent density in the second voltage range.

This makes it possible to suppress the degradation of linearity characteristics of the output with respect to the amount of incident light, while also maintaining a sufficient saturated signal amount, even in low-sensitivity imaging, thereby enabling a wide range of sensitivity control.

Moreover, for example, in the photocurrent characteristic, a maximum value of the photocurrent density in the first voltage range may be less than or equal to 10% of a photocurrent density value when the photocurrent density saturates as the voltage is increased.

This makes it possible to suppress the degradation of linearity characteristics of the output with respect to the amount of incident light, while also maintaining a sufficient saturated signal amount, even in the case where imaging is performed with a sensitivity less than or equal to one-tenth of the maximum sensitivity.

In addition, for example, in the photocurrent characteristics, an amount of change in photocurrent density per 0.5 V in the first voltage range may be less than or equal to 3% of a photocurrent density value when the photocurrent density saturates as the voltage is increased.

This makes it possible to further suppress the degradation of linearity characteristics of the output with respect to the amount of incident light, even in low-sensitivity imaging.

Additionally, for example, in the photocurrent characteristic, magnitude of a ratio of change in photocurrent density at a voltage in the first voltage range may be less than or equal to 20% of magnitude of a ratio of change in photocurrent density at a voltage in the second voltage range.

This makes it possible to further suppress the degradation of linearity characteristics of the output with respect to the amount of incident light, even in low-sensitivity imaging.

Furthermore, for example, a thickness of the first charge blocking layer may be less than or equal to 50 nm.

Accordingly, when the voltage applied between the upper electrode and the lower electrode is increased, the charge accumulated at the interface between the photoelectric conversion layer and the first charge blocking layer can more easily pass through the first charge blocking layer. This makes it easier to suppress any potential reduction in the photoelectric conversion efficiency of the photoelectric conversion element.

In addition, for example, the photoelectric conversion element includes a second charge blocking layer located between the photoelectric conversion layer and the first electrode, and the second charge blocking layer may be configured to block charge of polarity opposite to that of the signal charge.

This makes it possible to reduce spurious signals caused by dark current, which adversely affect the signal-to-noise (SN) ratio.

Also, for example, a thickness of the first charge blocking layer may be less than a thickness of the second charge blocking layer.

This makes it possible to suppress any potential reduction in the photoelectric conversion efficiency of the photoelectric conversion element while suppressing dark current.

Additionally, for example, when the voltage applied between the first electrode and the second electrode is increased from 0 V, the photocurrent characteristic has a first inflection point that occurs because the photocurrent density changes sharply, and a second inflection point at a higher voltage than a voltage at the first inflection point. The first voltage range may be included in a voltage range between 0 V and the voltage at the first inflection point, and the second voltage range may be included in a voltage range between the voltage at the first inflection point and the voltage at the second inflection point.

This makes it possible to further suppress the degradation of linearity characteristics of the output with respect to the amount of incident light, even in low-sensitivity imaging.

Furthermore, an imaging device according to one aspect of the present disclosure includes the photoelectric conversion element, a charge detection circuit connected to the first electrode, and voltage supply circuitry that provides a potential difference between the first electrode and the second electrode.

This makes it possible to realize an imaging device that, when imaging with adjusted sensitivity, can suppress the degradation of linearity characteristics of the output with respect to the amount of incident light, while also maintaining a sufficient saturated signal amount, even in low-sensitivity imaging.

Hereinafter, an embodiment will be described with reference to the drawings.

Note that the embodiment described hereinafter is all illustrative of comprehensive or specific examples. The numerical values, shapes, components, component arrangement positions and connection forms, steps, and step sequences discussed in the following embodiment are merely examples and are not intended to limit the present disclosure. Additionally, any components in the following embodiment that are not described in the independent claims are explained as optional components. Furthermore, the drawings are not necessarily depicted to scale. In the drawings, substantially identical components are labeled with the same reference numerals, and redundant explanations may be omitted or simplified.

In addition, in this specification, terms indicating the relationships between elements, terms indicating the shapes of elements, and numerical ranges are not expressions that only strictly denote precise meanings, but are expressions encompassing substantially equivalent ranges, including deviations of a few percent, for example.

Moreover, in this specification, the terms “on” and “under” do not refer to upward (vertical upward) and downward (vertical downward) directions in absolute spatial recognition, but also used as terms defined by relative positional relationships based on the stacking order in a multilayer structure. Note that terms such as “on” and “under” are used only to specify the mutual arrangement of members, and are not intended to limit the position in the case of using the imaging device. Additionally, the terms “on” and “under” apply not only when two components are spaced apart with another component between them, but also when two components are closely positioned and are in contact with each other.

Also, in this specification, electromagnetic waves in general, including visible light, infrared light, and ultraviolet light, are referred to as “light” for convenience.

### EMBODIMENT

### Photoelectric Conversion Element

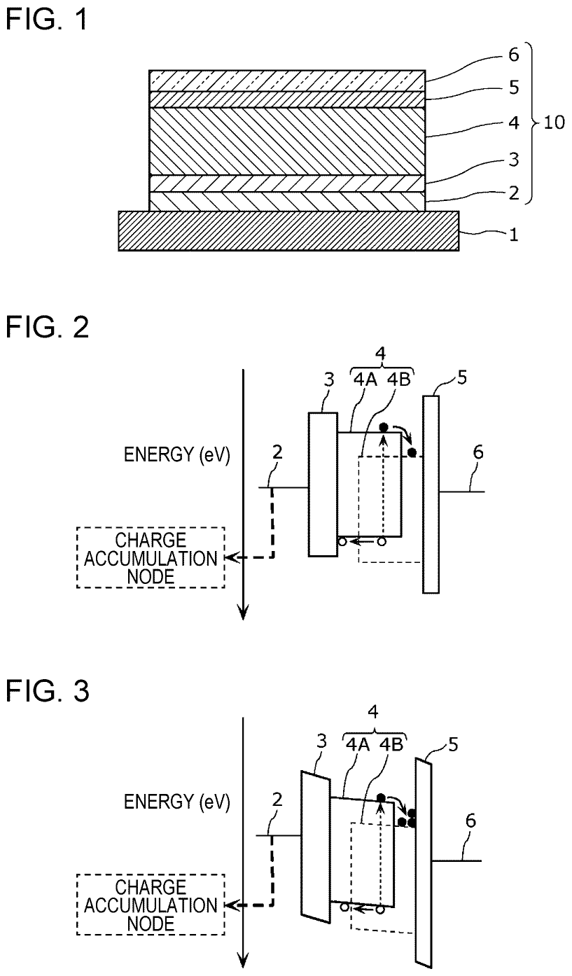

First, a photoelectric conversion element included in an imaging device according to the present embodiment will be described using FIG. 1. The photoelectric conversion element according to the present embodiment is a charge readout type photoelectric conversion element. FIG. 1 is a schematic cross-sectional view illustrating the configuration of a photoelectric conversion element 10 according to the present embodiment.

As illustrated in FIG. 1, the photoelectric conversion element 10 is supported on a supporting substrate 1, and includes a pair of electrodes, namely, an upper electrode 6 and a lower electrode 2, a photoelectric conversion layer 4 located between the upper electrode 6 and the lower electrode 2, a charge blocking layer 3 located between the lower electrode 2 and the photoelectric conversion layer 4, and a charge blocking layer 5 located between the photoelectric conversion layer 4 and the upper electrode 6. In the present embodiment, the lower electrode 2 is an example of a first electrode, and the upper electrode 6 is an example of a second electrode. Moreover, the charge blocking layer 5 is an example of a first charge blocking layer, and the charge blocking layer 3 is an example of a second charge blocking layer.

The photoelectric conversion element 10 is used, for example, at a position where light transmitted through the upper electrode 6 and the charge blocking layer 5 is incident onto the photoelectric conversion layer 4.

Hereinafter, each component of the photoelectric conversion element 10 according to the present embodiment will be described.

The supporting substrate 1 may be any general substrate used for supporting a photoelectric conversion element, such as a glass substrate, a quartz substrate, a semiconductor substrate, or a plastic substrate.

The lower electrode 2 is formed of a metal, metal nitride, metal oxide, conductive polysilicon, or the like. Examples of metals include aluminum, copper, titanium, and tungsten. An example of imparting conductivity to polysilicon is doping impurities.

The upper electrode 6 is, for example, a transparent electrode formed of a transparent conductive material. Materials for the upper electrode 6 include, for example, transparent conducting oxide (TCO), indium tin oxide (ITO), indium zinc oxide (IZO), aluminum-doped zinc oxide (AZO), fluorine-doped tin oxide (FTO), SnO₂, TiO₂, and the like. Note that the upper electrode 6 may be fabricated from a TCO and metal materials such as aluminum (Al) and gold (Au), either individually or in various combinations, as appropriate, depending on the desired transmittance.

Note that the materials for the lower electrode 2 and the upper electrode 6 are not limited to the above-mentioned conductive materials, and other materials may be used.

Various methods are used to fabricate the lower electrode 2 and the upper electrode 6, depending on the materials used. For example, when using ITO, methods such as electron beam deposition, sputtering, resistance heating evaporation, sol-gel chemical reaction methods, or coating with a dispersion of indium tin oxide may be employed. In this case, for the fabrication of the lower electrode 2 and the upper electrode 6, after depositing the ITO film, additional treatments such as UV-ozone treatment, plasma treatment, etc. may be applied.

The photoelectric conversion layer 4 contains a donor semiconductor material and an acceptor semiconductor material. The photoelectric conversion layer 4 is fabricated using, for example, organic semiconductor materials. As methods for fabricating the photoelectric conversion layer 4, for example, wet methods such as spin coating or dry methods such as vacuum evaporation may be used. Vacuum evaporation is a method in which the material of the layer is vaporized by heating under vacuum and then deposited on the substrate.

Additionally, the photoelectric conversion layer 4 is, for example, a mixed film with a bulk-heterojunction structure containing a donor organic semiconductor material and an acceptor organic semiconductor material. Hereinafter, donor organic semiconductor materials and acceptor organic semiconductor materials will be specifically explained.

Donor organic semiconductor materials include, for example, triarylamine compounds, benzidine compounds, pyrazoline compounds, styryl amine compounds, hydrazone compounds, triphenylmethane compounds, carbazole compounds, polysilane compounds, thiophene compounds, phthalocyanine compounds, naphthalocyanine compounds, subphthalocyanine compounds, cyanine compounds, merocyanine compounds, oxonol compounds, polyamine compounds, indole compounds, pyrrole compounds, pyrazole compounds, biphenyl compounds, terphenyl compounds, polyarylene compounds, condensed aromatic carbon ring compounds, and metal complexes having nitrogen-containing heterocyclic compounds as ligands.

Condensed aromatic carbon ring compounds include, for example, naphthalene derivatives, anthracene derivatives, phenanthrene derivatives, tetracene derivatives, pyrene derivatives, perylene derivatives, and fluoranthene derivatives.

Acceptor organic semiconductor materials include, for example, fullerenes, fullerene derivatives, condensed aromatic carbon ring compounds, 5- to 7-membered heterocyclic compounds containing nitrogen, oxygen, and sulfur atoms, polyallylene compounds, fluorene compounds, cyclopentadiene compounds, silyl compounds, and metal complexes having nitrogen-containing heterocyclic compounds as ligands.

Fullerenes include, for example, C60 fullerene and C70 fullerene.

Fullerene derivatives include, for example, phenyl-C₆₁-butyric acid methyl ester (PCBM) and indene-C₆₀ bis-adducts (ICBA).

The 5- to 7-membered heterocyclic compounds containing nitrogen, oxygen, and sulfur atoms include, for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzodiazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, and tribenzazepine.

Note that the donor organic semiconductor materials and the acceptor organic semiconductor materials are not limited to the above-mentioned examples. Organic compounds, whether low molecular weight or high molecular weight, that can be deposited as the photoelectric conversion layer using either dry or wet methods, may be used as donor organic semiconductor materials and acceptor organic semiconductor materials constituting the photoelectric conversion layer 4.

Moreover, the photoelectric conversion layer 4 may also include semiconductor materials other than organic semiconductor materials as donor semiconductor materials and acceptor semiconductor materials. The photoelectric conversion layer 4 may contain, as semiconductor materials, silicon semiconductors, compound semiconductors, quantum dots, perovskite materials, carbon nanotubes, or mixtures thereof including two or more of these materials.

The photoelectric conversion element 10 according to the present embodiment includes the charge blocking layer 3 provided between the lower electrode 2 and the photoelectric conversion layer 4 and the charge blocking layer 5 provided between the upper electrode 6 and the photoelectric conversion layer 4. The charge blocking layer 3 is, for example, in contact with the lower electrode 2 and the photoelectric conversion layer 4. The charge blocking layer 5 is, for example, in contact with the upper electrode 6 and the photoelectric conversion layer 4.

The charge blocking layer 3 contains a second charge blocking material. The charge blocking layer 5 contains a first charge blocking material. As materials used for the charge blocking layer 3 and the charge blocking layer 5, semiconductor materials or insulator materials with the energy bands described later are used. The charge blocking layer 3 and the charge blocking layer 5 are formed of, for example, organic semiconductor materials. Organic semiconductor materials are, for example, the above-mentioned donor organic semiconductor materials. The materials used to form the charge blocking layer 3 and the charge blocking layer 5 are not limited to organic semiconductor materials; they may also include oxide semiconductors, nitride semiconductors, insulators, or composite materials thereof. The materials used to form the charge blocking layer 3 and the charge blocking layer 5 may be metal oxides such as aluminum oxide, for example.

The charge blocking layer 5 may contain the same materials as the charge blocking layer 3. Additionally, the charge blocking layer 5 may contain the same materials as donor semiconductor materials contained in the photoelectric conversion layer 4.

FIG. 2 is an exemplary energy band diagram of the photoelectric conversion element illustrated in FIG. 1. In FIG. 2, the energy band of each layer is depicted as a rectangle. Also, in FIG. 2, electrons are depicted as black circles and holes as white circles, illustrating schematically some of the movements of electrons and holes.

The photoelectric conversion layer 4 generates excitons internally when illuminated by light. The generated excitons diffuse within the photoelectric conversion layer 4 and are separated into electrons and holes at the interface between the acceptor semiconductor material and the donor semiconductor material. The separated electrons and holes each move, according to the electric field applied to the photoelectric conversion layer 4, towards the lower electrode 2 side or the upper electrode 6 side, respectively. When a voltage is applied between the upper electrode 6 and the lower electrode 2 so that the potential of the upper electrode 6 becomes higher than the potential of the lower electrode 2, electrons move to the upper electrode 6 side and holes move to the lower electrode 2 side. When the photoelectric conversion element 10 is used in an imaging device, for example, holes are collected by the lower electrode 2 and accumulated as signal charge in a charge accumulation node electrically connected to the lower electrode 2. The charge accumulation node is at least a portion of a charge accumulation region for accumulating signal charge collected by the lower electrode 2. In this way, the photoelectric conversion layer 4 converts light into signal charge, and the lower electrode 2 collects the signal charge generated in the photoelectric conversion layer 4. Additionally, the upper electrode 6 collects charge of polarity opposite to that of the signal charge. Hereinafter, the case in which holes move to the lower electrode 2 side and are used as signal charge will be described. Alternatively, electrons may be used as the signal charge.

Here, among the pairs of electrons and holes generated by light absorption, the material that donates electrons to the other material is referred to as a donor material, and the material that accepts electrons is referred to as an acceptor material. In the present embodiment, the donor semiconductor material is the donor material, and the acceptor semiconductor material is the acceptor material. When using two different types of organic semiconductor materials, which material serves as the donor and which as the acceptor is generally determined by the relative positions of their highest occupied molecular orbital (HOMO) and lowest unoccupied molecular orbital (LUMO) energy levels at the contacting interface. Of the rectangles indicating the energy bands in FIG. 2, the upper edge corresponds to the energy level of LUMO, and the lower edge corresponds to the energy level of HOMO. Furthermore, the energy difference between the vacuum level and the energy level of LUMO is referred to as the electron affinity. Moreover, the energy difference between the vacuum level and the energy level of HOMO is referred to as the ionization potential. In FIG. 2, the lower the position, the greater the electron affinity and ionization potential.

As illustrated in FIG. 2, of the two types of semiconductor materials contained in the photoelectric conversion layer 4, the one with a shallower LUMO energy level, meaning a smaller electron affinity, serves as a donor semiconductor material 4A, which is the donor material. Also, of the two types of semiconductor materials contained in the photoelectric conversion layer 4, the one with a deeper LUMO energy level, meaning a larger electron affinity, serves as an acceptor semiconductor material 4B, which is the acceptor material. Although the energy band of the donor semiconductor material 4A and the energy band of the acceptor semiconductor material 4B are illustrated in FIG. 2 as being shifted laterally, this is for the sake of clarity and does not imply that the donor semiconductor material 4A and the acceptor semiconductor material 4B are distributed separately in the thickness direction of the photoelectric conversion layer 4. Additionally, the energy band of the acceptor semiconductor material 4B is depicted as a dashed-line rectangle; this is again for the sake of clarity and is not intended to be distinguished from a solid-line rectangle.

The ionization potential of the donor semiconductor material 4A is, for example, less than the ionization potential of the acceptor semiconductor material 4B.

In FIG. 2, the electron affinity and ionization potential of the charge blocking layer 3 are, for example, the electron affinity and ionization potential of the second charge blocking material contained in the charge blocking layer 3. Additionally, the electron affinity and ionization potential of the charge blocking layer 5 are, for example, the electron affinity and ionization potential of the first charge blocking material contained in the charge blocking layer 5.

The charge blocking layer 3 is configured to block charge of polarity opposite to that of the signal charge. The electron affinity of the charge blocking layer 3 is, for example, less than or equal to the electron affinity of the acceptor semiconductor material 4B of the photoelectric conversion layer 4. The charge blocking layer 3 suppresses the injection of charge (specifically, electrons) of polarity opposite to that of the signal charge from the lower electrode 2 to the photoelectric conversion layer 4. This makes it possible to reduce spurious signals caused by dark current, which adversely affect the signal-to-noise (SN) ratio.

In addition, the charge blocking layer 5 is configured to block charge of polarity opposite to that of the signal charge. The electron affinity of the charge blocking layer 5 is less than the electron affinity of the acceptor semiconductor material 4B. Additionally, the electron affinity of the charge blocking layer 5 may be at least 1 eV less than the electron affinity of the acceptor semiconductor material 4B.

By providing the charge blocking layer 5 having an electron affinity that is less than the electron affinity of the acceptor semiconductor material 4B as mentioned earlier, electrons generated in the photoelectric conversion layer 4 can be accumulated at the interface between the photoelectric conversion layer 4 and the charge blocking layer 5. In particular, if the electron affinity of the charge blocking layer 5 is at least 1 eV less than the electron affinity of the acceptor semiconductor material 4B, electrons generated in the photoelectric conversion layer 4 are easily accumulated at the interface between the photoelectric conversion layer 4 and the charge blocking layer 5.

Also, the ionization potential of the charge blocking layer 5 is greater than or equal to, for example, the ionization potential of the donor semiconductor material 4A. Accordingly, the charge blocking layer 5 suppresses the injection of signal charge (specifically, holes) from the upper electrode 6 to the photoelectric conversion layer 4. This makes it possible to reduce spurious signals that adversely affect the SN ratio.

FIG. 3 is an energy band diagram in the case where a low voltage is applied between the upper electrode 6 and the lower electrode 2 in the photoelectric conversion element 10 having the energy band configuration illustrated in FIG. 2 so that the potential of the upper electrode 6 becomes higher than the potential of the lower electrode 2. In FIG. 3, as in FIG. 2, electrons are depicted as black circles and holes as white circles, illustrating schematically some of the movements of electrons and holes. In this specification, the voltage applied between the upper electrode 6 and the lower electrode 2 may be referred to as the “bias voltage”.

As illustrated in FIG. 3, electrons generated in the photoelectric conversion layer 4 are accumulated at the interface between the photoelectric conversion layer 4 and the charge blocking layer 5. The accumulated electrons in the photoelectric conversion layer 4 create space charge and relax the electric field. Also, the electrons accumulated at the interface between the photoelectric conversion layer 4 and the charge blocking layer 5 can recombine with holes. Due to these effects of electric field relaxation and recombination, the signal charge extracted to the lower electrode 2 is very small, and the amount extracted is less likely to change even if the bias voltage changes.

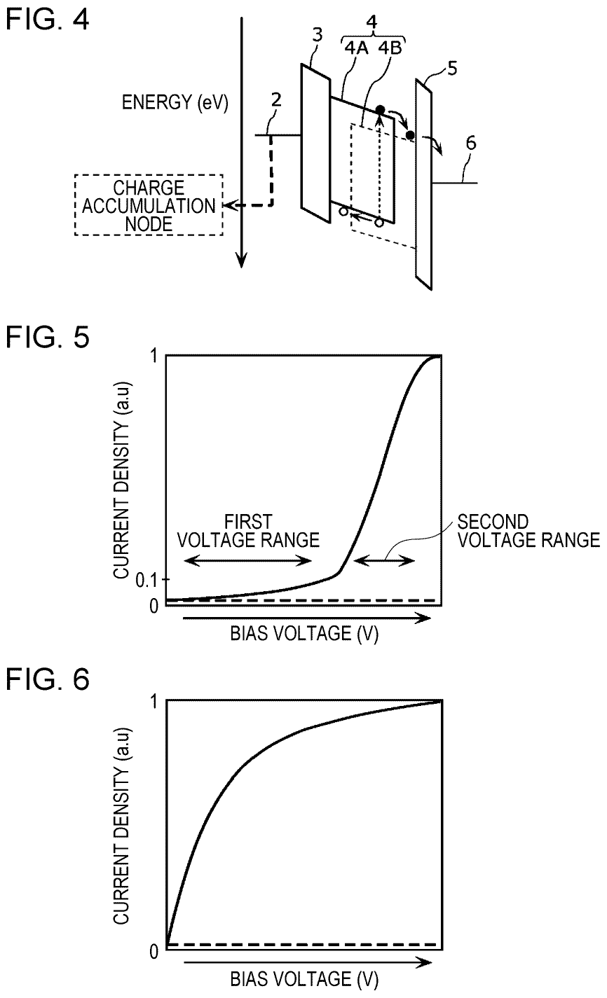

FIG. 4 is also an energy band diagram in the case where a higher voltage than the case illustrated in FIG. 3 is applied between the upper electrode 6 and the lower electrode 2 in the photoelectric conversion element 10 having the energy band configuration illustrated in FIG. 2 so that the potential of the upper electrode 6 becomes higher than the potential of the lower electrode 2. If the electric field intensity of the charge blocking layer 5 is sufficiently strong, electrons accumulated at the interface between the photoelectric conversion layer 4 and the charge blocking layer 5 have enough energy to pass through the charge blocking layer 5 and are extracted to the upper electrode 6. In doing so, the effect of electric field relaxation is reduced, and the amount of signal charge extracted to the lower electrode 2 is increased.

In this way, within the voltage range until a voltage sufficient for the electrons accumulated at the interface between the photoelectric conversion layer 4 and the charge blocking layer 5 to have enough energy to pass through the charge blocking layer 5 is applied, the state is as illustrated in FIG. 3. Therefore, the photoelectric conversion element 10 can maintain low sensitivity over a wide voltage range.

The thickness of the charge blocking layer 3 is, for example, greater than or equal to 2 nm, and may be greater than or equal to 5 nm. This makes it easier to ensure the function of suppressing the injection of charge from the lower electrode 2. As a result, dark current can be suppressed. In addition, the thickness of the charge blocking layer 3 is, for example, less than or equal to 70 nm, and may be less than or equal to 50 nm. This makes it possible to suppress the reduction in the photoelectric conversion efficiency of the photoelectric conversion element 10.

The thickness of the charge blocking layer 5 is, for example, greater than or equal to 2 nm, and may be greater than or equal to 5 nm. This makes it easier to accumulate electrons at the interface between the photoelectric conversion layer 4 and the charge blocking layer 5, and allows for a wider range of voltages to be applied between the upper electrode 6 and the lower electrode 2 when reducing sensitivity. In addition, the thickness of the charge blocking layer 5 is, for example, less than or equal to 50 nm, and may be less than or equal to 30 nm. Accordingly, when the voltage applied between the upper electrode 6 and the lower electrode 2 is increased, electrons accumulated at the interface between the photoelectric conversion layer 4 and the charge blocking layer 5 can more easily pass through the charge blocking layer 5. This makes it easier to suppress any potential reduction in the photoelectric conversion efficiency of the photoelectric conversion element 10. Additionally, the thickness of the charge blocking layer 5 is, for example, less than the thickness of the charge blocking layer 3. This makes it possible to suppress any potential reduction in the photoelectric conversion efficiency of the photoelectric conversion element 10 while suppressing dark current.

The transmittance of light in the visible light range of the charge blocking layer 5 is, for example, greater than or equal to 50%, and may be greater than or equal to 70%. This makes it possible to suppress the reduction in the photoelectric conversion efficiency of the photoelectric conversion element 10. Furthermore, the transmittance of light, within the wavelength range absorbed by the photoelectric conversion layer 4, through the charge blocking layer 5 is, for example, greater than or equal to 50%, and may be greater than or equal to 70%.

### Current-Voltage Characteristics of Photoelectric Conversion Element

Next, the current-voltage characteristics of the photoelectric conversion element 10 will be described.

FIG. 5 is a diagram illustrating an example of the schematic current-voltage characteristics (I-V characteristics) of the photoelectric conversion element 10. In FIG. 5, the vertical axis indicates the density of current flowing between the lower electrode 2 and the upper electrode 6, and the horizontal axis indicates the voltage applied between the upper electrode 6 and the lower electrode 2.

In FIG. 5, the solid line graph illustrates the exemplary I-V characteristics of the photoelectric conversion element 10 when a voltage is applied between the upper electrode 6 and the lower electrode 2 under light irradiation. That is, the current density in the solid line graph is the photocurrent density corresponding to the current flowing in the state where the photoelectric conversion element 10 is irradiated with light. Here, being under light irradiation may refer to, for example, a condition of being irradiated with light of 1000 lux. Taking into consideration the standard illuminance indoors, being under light irradiation may refer to, for example, a condition of being irradiated with light of 300 lux or more. Note that the dashed line in FIG. 5 also illustrates an example of the I-V characteristics of the photoelectric conversion element 10 when a voltage is applied between the upper electrode 6 and the lower electrode 2 under no light irradiation. That is, the current density in the dashed line graph is the dark current density corresponding to the current flowing in a state where the photoelectric conversion element 10 is not irradiated with light.

Moreover, in FIG. 5, the current density is illustrated in arbitrary normalized units, and the photocurrent density value when the photocurrent density saturates as the bias voltage is increased is set to 1. In this specification, “the photocurrent density value when the photocurrent density saturates” refers to the photocurrent density value when the photocurrent density remains substantially unchanged as the bias voltage is increased. The photocurrent density value when the photocurrent density saturates is, for example, the photocurrent density value when the change in photocurrent density becomes less than or equal to 1% for a change of 1 V in bias voltage as the bias voltage is increased within a range that does not damage the photoelectric conversion element 10.

In FIG. 5, the I-V characteristics are illustrated, with the voltage applied to make the potential of the upper electrode 6 higher than the potential of the lower electrode 2 defined as a “positive” value. Therefore, FIG. 5 illustrates the photocurrent characteristics in the case where a voltage is applied between the lower electrode 2 and the upper electrode 6 such that holes, which constitute the signal charge, are collected at the lower electrode 2. Additionally, it could be said that the voltage and current density are represented in absolute values in FIG. 5. In this specification, the comparison of voltage and current density refers to the case when they are compared in absolute values.

As illustrated in FIG. 5, the photocurrent characteristics of the photoelectric conversion element 10 according to the present embodiment are schematically characterized by a first voltage range and a second voltage range. As illustrated in FIG. 5, voltages in the first voltage range are lower than voltages in the second voltage range. Also, in the first voltage range, the photocurrent density is greater than the dark current density. Additionally, the photocurrent density in the second voltage range is greater than the photocurrent density in the first voltage range. Furthermore, the ratio of change in photocurrent density with respect to voltage in the first voltage range is less than the ratio of change in photocurrent density with respect to voltage in the second voltage range. That is, the amount of increase in photocurrent density when the voltage is increased is smaller in the first voltage range than in the second voltage range. Moreover, at voltages higher than the second voltage range, the photocurrent density saturates and remains almost unchanged, stabilizing at a nearly constant value. The range of voltages in which the photocurrent density saturates may be referred to as a third voltage range.

The ratio of change in photocurrent density with respect to voltage is, in other words, the ratio of the amount of increase in photocurrent density to the amount of increase in voltage; it could also be said that it is the slope of the increase in photocurrent density relative to the increase in voltage in the current-voltage characteristics. Additionally, it could be said that the ratio of change in photocurrent density with respect to voltage is the slope of the tangent at a certain voltage in the current-voltage characteristics. Furthermore, in the first voltage range, the ratio of change in photocurrent density with respect to voltage is greater than 0.

In addition, the photocurrent characteristics of the photoelectric conversion element 10 exhibit, for example, a first inflection point and a second inflection point at a voltage higher than the voltage at the first inflection point. For example, the first voltage range is included in the voltage range between 0 V and the voltage at the first inflection point in the graph of the I-V characteristics, and the second voltage range is included in the voltage range between the voltage at the first inflection point and the voltage at the second inflection point in the graph of the I-V characteristics. The first inflection point is an inflection point that occurs when the photocurrent density sharply changes as the voltage is increased from 0 V. The voltage at the first inflection point is, for example, the voltage that corresponds to the maximum value in the second derivative of the graph of the I-V characteristics. Additionally, the second inflection point is an inflection point that occurs when the photocurrent density that has changed sharply saturates as the voltage is increased from the voltage at the first inflection point. The voltage at the second inflection point is, for example, the voltage that corresponds to the minimum value in the second derivative of the graph of the I-V characteristics.

The first voltage range corresponds, for example, to the voltage that results in the state illustrated in FIG. 3. When a voltage within the first voltage range is applied to the photoelectric conversion element 10, as illustrated and described with reference to FIG. 3, charge (electrons) accumulated at the interface between the photoelectric conversion layer 4 and the charge blocking layer 5 inside the photoelectric conversion element 10 causes electric field relaxation and recombination, thereby reducing the photocurrent density. In addition, due to the above-mentioned electric field relaxation and recombination, the signal charge collected in the lower electrode 2 does not increase rapidly even if the bias voltage increases, so the ratio of change in photocurrent density with respect to the bias voltage is small. Also, since the accumulated charge is of polarity opposite to that of the signal charge, a portion of the signal charge is collected in the lower electrode 2. That is, a photocurrent larger than the dark current flows, and the signal charge is accumulated in the charge accumulation node. This makes it possible to use voltages within the first voltage range for low-sensitivity imaging.

In contrast, the second voltage range corresponds, for example, to the voltage that results in the state illustrated in FIG. 4. When a voltage within the second voltage range is applied to the photoelectric conversion element 10, as illustrated and described with reference to FIG. 4, charge accumulated at the interface between the photoelectric conversion layer 4 and the charge blocking layer 5 inside the photoelectric conversion element 10 passes through the charge blocking layer 5, thereby increasing the photocurrent density. Additionally, the increase in bias voltage is directly linked to the increase in the energy required for the accumulated charge mentioned above to pass through the charge blocking layer 5, resulting in a greater ratio of change in photocurrent density with respect to bias voltage.

When the voltage applied to the photoelectric conversion element 10 exceeds the second voltage range, the energy required for the accumulated charge mentioned above to pass through the charge blocking layer 5 becomes sufficiently large. Therefore, the magnitude of the photocurrent density is determined by the amount of signal charge generated through the photoelectric conversion of the photoelectric conversion layer 4. Therefore, even if the bias voltage changes, the photocurrent density will hardly change, and if the amount of incident light remains constant, the current density will also remain almost constant.

In the case of using the photoelectric conversion element 10 in an imaging device, a bias voltage within the first voltage range is applied to the photoelectric conversion element 10 for low-sensitivity imaging. In addition, a bias voltage higher than the second voltage range is applied to the photoelectric conversion element 10 for high-sensitivity imaging (normal imaging). For example, applying a voltage within the range where the photocurrent density saturates to the photoelectric conversion element 10 maximizes sensitivity.

In the photoelectric conversion element 10 according to the present embodiment, the first voltage range can be widened by the presence of the charge blocking layer 5, and the width of the first voltage range is greater than or equal to 0.5 V. Here, the width of the first voltage range is, in other words, the absolute value of the difference between the maximum voltage of the first voltage range and the minimum voltage of the first voltage range. Additionally, when a bias voltage within the first voltage range is applied to the photoelectric conversion element 10, even if the bias voltage decreases due to the lower electrode 2 collecting holes, the change in photocurrent density is small, so the degradation of linearity characteristics of the output with respect to the amount of incident light can be suppressed. That is, even when signal charge accumulates in the charge accumulation region, the output signal amount in response to the amount of incident light hardly changes. Furthermore, since the width of the first voltage range is greater than or equal to 0.5 V, it is possible to increase the signal charge amount at which the charge accumulation region connected to the lower electrode 2 saturates, thereby maintaining a sufficient saturated signal amount. Note that the width of the first voltage range may be greater than or equal to 1 V, and may also be greater than or equal to 2 V. Additionally, the width of the first voltage range may be less than or equal to 5 V, and may also be less than or equal to 4V.

As described above, since the photoelectric conversion element 10 has the above-mentioned photocurrent characteristics, when the photoelectric conversion element 10 is used in an imaging device, the degradation of linearity characteristics of the output with respect to the amount of incident light can be suppressed even in low-sensitivity imaging, and also a sufficient saturated signal amount can be maintained. Furthermore, because the sensitivity can be changed depending on the bias voltage, there is no need to use a physical ND filter, and the sensitivity can be changed seamlessly.

In the photocurrent characteristics of the photoelectric conversion element 10, for example, the maximum value of the photocurrent density in the first voltage range is less than or equal to 10% of the maximum value of the photocurrent density in the second voltage range. This makes it possible to suppress the degradation of linearity characteristics of the output with respect to the amount of incident light, while also maintaining a sufficient saturated signal amount, even in yet lower-sensitivity imaging. Therefore, it is possible to expand the sensitivity range within which imaging can be performed while maintaining the quality of imaging. Additionally, for example, the maximum value of the photocurrent density in the first voltage range is greater than or equal to 1% of the maximum value of the photocurrent density in the second voltage range. Furthermore, for example, the maximum value of the photocurrent density in the first voltage range is greater than or equal to ten times the maximum dark current density in the first voltage range.

Moreover, in the photocurrent characteristics of the photoelectric conversion element 10, for example, the maximum value of the photocurrent density in the first voltage range may be less than or equal to 10% of the photocurrent density value when the photocurrent density saturates as the voltage is increased. Accordingly, even in the case where imaging is performed with sensitivity less than or equal to one-tenth of the maximum sensitivity, the degradation of linearity characteristics of the output with respect to the amount of incident light can be suppressed, and a sufficient saturated signal amount can be maintained. Hence, it becomes possible to control the luminance values of images even in environments with significant differences in illuminance. Additionally, for example, the maximum value of the photocurrent density in the first voltage range is greater than or equal to 1% of the photocurrent density value when the photocurrent density saturates as the voltage is increased.

Also, in the photocurrent characteristics of the photoelectric conversion element 10, for example, the amount of change in photocurrent density per 0.5 V in the first voltage range is less than or equal to 3% of the photocurrent density value when the photocurrent density saturates as the voltage is increased. This makes it possible to further suppress the degradation of linearity characteristics of the output with respect to the amount of incident light, even in low-sensitivity imaging. In addition, for example, the amount of change in photocurrent density per 0.5 V in the first voltage range is greater than or equal to 0.1% of the photocurrent density value when the photocurrent density saturates as the voltage is increased.

Furthermore, in the photocurrent characteristics of the photoelectric conversion element 10, for example, the magnitude of the ratio of change in photocurrent density with respect to voltage in the first voltage range is less than or equal to 20% of the magnitude of the ratio of change in photocurrent density with respect to voltage in the second voltage range. This makes it possible to further suppress the degradation of linearity characteristics of the output with respect to the amount of incident light, even in low-sensitivity imaging. Furthermore, for example, the magnitude of the ratio of change in photocurrent density with respect to voltage in the first voltage range is greater than or equal to 1% of the magnitude of the ratio of change in photocurrent density with respect to voltage in the second voltage range.

Note that, when using electrons as the signal charge, if the voltage applied to make the potential of the lower electrode 2 higher than the potential of the upper electrode 6 is defined as a “positive” value, the photoelectric conversion element exhibits photocurrent characteristics as illustrated in FIG. 5.

FIG. 6 is a diagram illustrating an example of the schematic current-voltage characteristics of a conventional photoelectric conversion element. In FIG. 6, the solid line graph illustrates the exemplary I-V characteristics of the conventional photoelectric conversion element when a voltage is applied between the upper electrode 6 and the lower electrode 2 under light irradiation. Note that the dashed line in FIG. 6 also illustrates an example of the I-V characteristics of the conventional photoelectric conversion element when a voltage is applied between the upper electrode 6 and the lower electrode 2 under no light irradiation. The conventional photoelectric conversion element has, for example, a configuration without the charge blocking layer 5 according to the present embodiment, and, even if a low bias voltage is applied to the photoelectric conversion element, almost no electrons are accumulated in the photoelectric conversion element and are collected in the upper electrode 6.

Specifically, as illustrated in FIG. 6, in the conventional photoelectric conversion element, there is no electric field relaxation effect due to charge accumulated at the interface between the photoelectric conversion layer 4 and the charge blocking layer 5 as mentioned earlier, and the photocurrent density increases sharply from around 0 V. Therefore, in the photocurrent characteristics of the conventional photoelectric conversion element, they either do not substantially have the first voltage range as mentioned earlier, or if they do, the first voltage range is very narrow. Therefore, in low-sensitivity imaging, when holes are collected in the lower electrode 2, the potential of the lower electrode 2 increases, and, when the bias voltage decreases, the photocurrent density changes sharply, leading to the significant degradation of linearity characteristics of the output with respect to the amount of incident light. In contrast, the photoelectric conversion element 10 according to the present embodiment has photocurrent characteristics with the first voltage range, as mentioned earlier, having a width of 0.5 V or more. Therefore, even in low-sensitivity imaging, it can suppress the degradation of linearity characteristics of the output with respect to the amount of incident light and maintain a sufficient saturated signal amount.

### Imaging Device

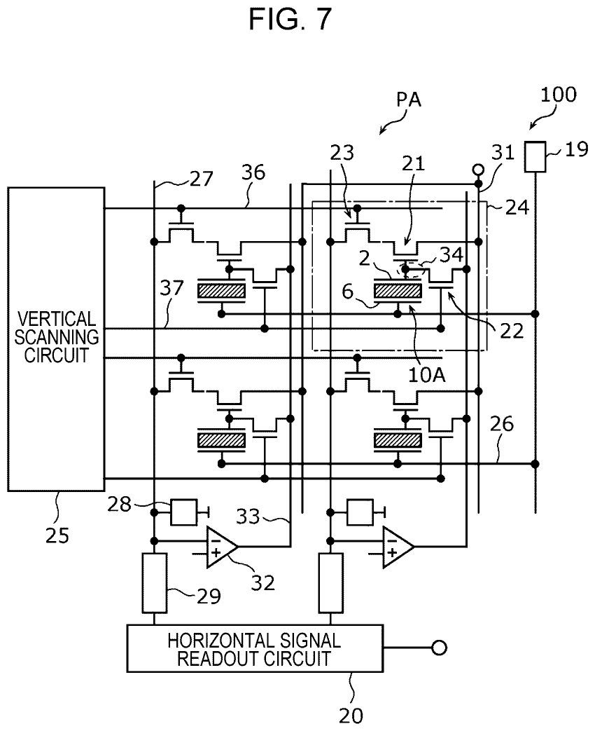

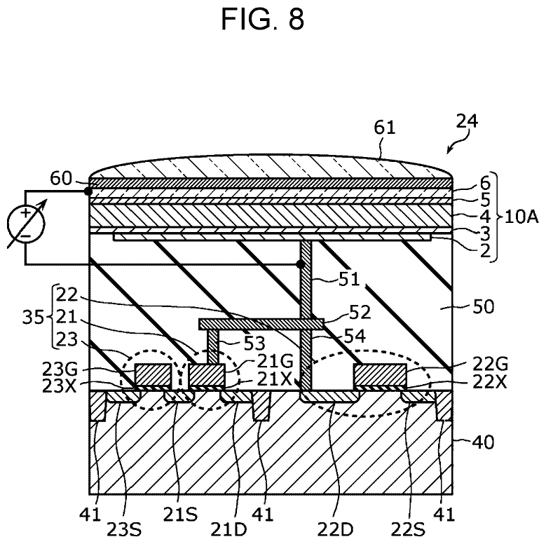

Hereinafter, an imaging device according to the present embodiment will be described with reference to FIGS. 7 and 8. FIG. 7 is a diagram illustrating an example of the circuit configuration of an imaging device 100 mounted with a photoelectric conversion unit 10A using the photoelectric conversion element 10 illustrated in FIG. 1. Also, FIG. 8 is a schematic cross-sectional view illustrating an example of the device structure of a pixel 24 in the imaging device 100 according to the present embodiment.

As illustrated in FIGS. 7 and 8, the imaging device 100 according to the present embodiment includes a semiconductor substrate 40 and pixels 24 each including a charge detection circuit 35 provided on the semiconductor substrate 40, the photoelectric conversion unit 10A provided on the semiconductor substrate 40, and a charge accumulation node 34 electrically connected to the charge detection circuit 35 and the photoelectric conversion unit 10A. The photoelectric conversion unit 10A of each of the pixels 24 includes the photoelectric conversion element 10 mentioned earlier. That is, each of the pixels 24 includes the upper electrode 6, the lower electrode 2, the photoelectric conversion layer 4, the charge blocking layer 5, the charge blocking layer 3, and the charge accumulation node 34. The charge accumulation node 34 is an example of a charge accumulation region.

In the photoelectric conversion unit 10A, the upper electrode 6, the charge blocking layer 5, the photoelectric conversion layer 4, the charge blocking layer 3, and the lower electrode 2 are arranged in this order from the light-incident side of the imaging device 100. The charge blocking layer 5 is located on the light-incident side of the photoelectric conversion layer 4. Light that has transmitted through the upper electrode 6 and the charge blocking layer 5 is incident on the photoelectric conversion layer 4. Therefore, excitons are more likely to be generated on the side of the photoelectric conversion layer 4 facing the charge blocking layer 5. In addition, in the present embodiment, the light-incident side of the imaging device 100 is opposite to the side of the photoelectric conversion unit 10A facing the semiconductor substrate 40.

The charge accumulation node 34 accumulates the charge obtained in the photoelectric conversion unit 10A, and the charge detection circuit 35 detects the charge accumulated in the charge accumulation node 34. Note that the charge detection circuit 35 provided with the semiconductor substrate 40 may be located either on the surface of the semiconductor substrate 40 or directly within the semiconductor substrate 40.

As illustrated in FIG. 7, the imaging device 100 includes pixels 24 and peripheral circuits. The imaging device 100 is, for example, an organic image sensor implemented with a one-chip integrated circuit and has a pixel array PA including the pixels 24 arranged in two dimensions.

The pixels 24 are arranged in two dimensions on the semiconductor substrate 40, i.e., in row and column directions, to form a photosensitive region, which is a pixel region. FIG. 7 depicts an example in which the pixels 24 are arranged in a matrix of two rows and two columns. Note that, in FIG. 7, for convenience of illustration, a circuit (for example, a pixel electrode control circuit) used to individually set the sensitivity of the pixels 24 is omitted. The imaging device 100 may also be a line sensor. In that case, the pixels 24 may be arranged in one dimension. Note that the row and column directions in this specification respectively refer to the directions in which rows and columns extend. That is, in FIG. 7, the vertical direction on the page corresponds to the column direction, and the horizontal direction corresponds to the row direction.

As illustrated in FIGS. 7 and 8, each pixel 24 includes the photoelectric conversion unit 10A, and the charge accumulation node 34 electrically connected to the charge detection circuit 35. The charge detection circuit 35 includes an amplifier transistor 21, a reset transistor 22, and an address transistor 23.

The photoelectric conversion unit 10A includes the lower electrode 2 provided as a pixel electrode and the upper electrode 6 provided as an opposing electrode facing the pixel electrode. The photoelectric conversion unit 10A includes the photoelectric conversion element 10 mentioned earlier. The upper electrode 6 is supplied with a voltage for applying a certain bias voltage via an opposing electrode signal line 26.

The lower electrode 2 is connected to a gate electrode 21G of the amplifier transistor 21, and the signal charge collected by the lower electrode 2 is accumulated in the charge accumulation node 34 located between the lower electrode 2 and the gate electrode 21G of the amplifier transistor 21. In the present embodiment, the signal charge comprises holes. That is, the charge accumulation node 34 is electrically connected to the lower electrode 2 and accumulates holes among the excitons generated in the photoelectric conversion layer 4.

The signal charge accumulated in the charge accumulation node 34 is applied as a voltage in response to the amount of the signal charge to the gate electrode 21G of the amplifier transistor 21. The amplifier transistor 21 amplifies this voltage and the amplified voltage is selectively read out as a signal voltage by the address transistor 23. The reset transistor 22 has its source/drain electrodes connected to the lower electrode 2 and resets the signal charge accumulated in the charge accumulation node 34. In other words, the reset transistor 22 resets the potential of the gate electrode 21G of the amplifier transistor 21 and the lower electrode 2.

In order to selectively perform the above-mentioned operation in the pixels 24, the imaging device 100 has a power supply wiring 31, a vertical signal line 27, an address signal line 36, and a reset signal line 37, which are connected to each pixel 24. Specifically, the power supply wiring 31 is connected to the source/drain electrodes of the amplifier transistor 21, and the vertical signal line 27 is connected to the source/drain electrodes of the address transistor 23. The address signal line 36 is connected to a gate electrode 23G of the address transistor 23. Also, the reset signal line 37 is connected to a gate electrode 22G of the reset transistor 22.

The peripheral circuits include voltage supply circuitry 19, a vertical scanning circuit 25, a horizontal signal readout circuit 20, column signal processing circuits 29, load circuits 28, and differential amplifiers 32.

The voltage supply circuitry 19 is electrically connected to the upper electrode 6 via the opposing electrode signal line 26. The voltage supply circuitry 19 supplies a voltage to the upper electrode 6 to provide a potential difference between the upper electrode 6 and the lower electrode 2. In the case where the signal charge comprises holes, the voltage supply circuitry 19 supplies a voltage to the upper electrode 6 such that the potential of the upper electrode 6 becomes higher than the potential of the lower electrode 2. Note that, in the case where the signal charge comprises electrons, the voltage supply circuitry 19 supplies a voltage to the upper electrode 6 such that the potential of the upper electrode 6 becomes lower than the potential of the lower electrode 2.

As will be explained in detail later, the sensitivity of the photoelectric conversion unit 10A is controlled by switching the voltage supplied from the voltage supply circuitry 19 to the upper electrode 6 among different voltages. The voltage supply circuitry 19 is not limited to a particular power supply circuit and may be a circuit that generates a certain voltage or a circuit that converts a voltage supplied from another power supply to a certain voltage. Note that the imaging device 100 need not be provided with the voltage supply circuitry 19. For example, the upper electrode 6 may be supplied with a voltage from an external power supply.

The vertical scanning circuit 25 is connected to the address signal line 36 and the reset signal line 37, and selects pixels 24 arranged in rows on a row-by-row basis to read out the signal voltage and reset the potential of the lower electrode 2. The power supply wiring 31, which serves as a source follower power supply, supplies a certain power supply voltage to each pixel 24. The horizontal signal readout circuit 20 is electrically connected to the column signal processing circuits 29. Each column signal processing circuit 29 is electrically connected to pixels 24 arranged in that column via its respective vertical signal line 27 corresponding to that column. Each load circuit 28 is electrically connected to its respective vertical signal line 27. Each load circuit 28 and the amplifier transistor 21 form a source follower circuit.

The differential amplifiers 32 are provided corresponding to the individual columns. An inverting input terminal of each differential amplifier 32 is connected to its corresponding vertical signal line 27. In addition, an output terminal of each differential amplifier 32 is connected to pixels 24 via its respective feedback line 33 corresponding to that column.

The vertical scanning circuit 25 applies a row selection signal, which controls the on/off state of the address transistor 23, to the gate electrode 23G of the address transistor 23 via the address signal line 36. By doing so, the row to be read out is scanned and selected. The signal voltage is read out from the pixels 24 in the selected row to the vertical signal line 27. Additionally, the vertical scanning circuit 25 applies a reset signal, which controls the on and off state of the reset transistor 22, to the gate electrode 22G of the reset transistor 22 via the reset signal line 37. By doing so, the row of pixels 24 targeted for the reset operation is selected. The vertical signal line 27 transfers the signal voltage read out from the pixels 24 selected by the vertical scanning circuit 25 to the column signal processing circuit 29.

The column signal processing circuit 29 performs operations such as noise suppression signal processing, exemplified by correlation double sampling, and analog-to-digital conversion (AD conversion).

The horizontal signal readout circuit 20 sequentially reads out signals from the column signal processing circuits 29 onto horizontal common signal lines (not illustrated).

The differential amplifier 32 is connected to the drain electrode of the reset transistor 22 via the feedback line 33. Accordingly, the differential amplifier 32 receives the output value of the address transistor 23 at its inverting input terminal. The differential amplifier 32 performs a feedback operation so that the gate potential of the amplifier transistor 21 becomes a certain feedback voltage. At this time, the output voltage value of the differential amplifier 32 is, for example, 0 V or a positive voltage near 0V. The feedback voltage means the output voltage of the differential amplifier 32.

As illustrated in FIG. 8, each pixel 24 includes the semiconductor substrate 40, the charge detection circuit 35, the photoelectric conversion unit 10A, and the charge accumulation node 34 (see FIG. 7).

The semiconductor substrate 40 may be an insulating substrate or the like, provided with a semiconductor layer on the surface where a photosensitive region is formed, and is, for example, a p-type silicon substrate. The semiconductor substrate 40 has impurity regions 21D, 21S, 22D, 22S, and 23S, and an element isolation region 41 for electrical isolation between pixels 24. The impurity regions 21D, 21S, 22D, 22S, and 23S are, for example, n-type regions. Here, the element isolation region 41 is provided between the impurity region 21D and the impurity region 22D. This suppresses leakage of the signal charge accumulated in the charge accumulation node 34. Note that the element isolation region 41 is formed, for example, by performing ion implantation of an acceptor under certain implantation conditions.

The impurity regions 21D, 21S, 22D, 22S, and 23S are, for example, diffusion regions formed in the semiconductor substrate 40. As illustrated in FIG. 8, the amplifier transistor 21 includes the impurity region 21S, the impurity region 21D, and the gate electrode 21G. The impurity region 21S and the impurity region 21D respectively function as, for example, a source region and a drain region of the amplifier transistor 21. Between the impurity region 21S and the impurity region 21D, a channel region of the amplifier transistor 21 is formed.

Similarly, the address transistor 23 includes the impurity region 23S, the impurity region 21S, and the gate electrode 23G connected to the address signal line 36. In this example, the amplifier transistor 21 and the address transistor 23 are electrically connected to each other by sharing the impurity region 21S. The impurity region 23S functions as, for example, a source region of the address transistor 23. The impurity region 23S has a connection with the vertical signal line 27 illustrated in FIG. 7.

The reset transistor 22 includes the impurity regions 22D and 22S, and the gate electrode 22G connected to the reset signal line 37. The impurity region 22S functions as, for example, a source region of the reset transistor 22. The impurity region 22S has a connection with the reset signal line 37 illustrated in FIG. 7.

The semiconductor substrate 40 is stacked with an interlayer insulating layer 50 so as to cover the amplifier transistor 21, the address transistor 23, and the reset transistor 22.

Additionally, a wiring layer (not illustrated) may be arranged in the interlayer insulating layer 50. The wiring layer may be formed of metal, such as copper, and may include as part thereof wiring such as the vertical signal line 27 mentioned earlier, for example. The number of insulating layers in the interlayer insulating layer 50 and the number of layers included in the wiring layer arranged in the interlayer insulating layer 50 can be arbitrarily set.

In the interlayer insulating layer 50, a contact plug 53 connected to the impurity region 22D of the reset transistor 22, a contact plug 51 connected to the lower electrode 2, and a wiring 52 connecting the contact plug 51, a contact plug 54, and the contact plug 53 are arranged. Accordingly, the impurity region 22D of the reset transistor 22 is electrically connected to the gate electrode 21G of the amplifier transistor 21. In the configuration illustrated in FIG. 8, the contact plugs 51, 53, and 54, the wiring 52, the gate electrode 21G of the amplifier transistor 21, and the impurity region 22D of the reset transistor 22 constitute at least a portion of the charge accumulation node 34.

The charge detection circuit 35 detects the signal charge collected by the lower electrode 2 and outputs a signal voltage. The charge detection circuit 35 includes the amplifier transistor 21, the reset transistor 22, and the address transistor 23, and is formed on or in the semiconductor substrate 40.

The amplifier transistor 21 includes the impurity region 21D and the impurity region 21S formed in the semiconductor substrate 40 and respectively functioning as a drain electrode and a source electrode, a gate insulating layer 21X formed on the semiconductor substrate 40, and the gate electrode 21G formed on the gate insulating layer 21X.

The reset transistor 22 includes the impurity region 22D and the impurity region 22S formed in the semiconductor substrate 40 and respectively functioning as a drain electrode and a source electrode, a gate insulating layer 22X formed on the semiconductor substrate 40, and the gate electrode 22G formed on the gate insulating layer 22X.

The address transistor 23 includes the impurity regions 21S and 23S formed in the semiconductor substrate 40 and respectively functioning as a drain electrode and a source electrode, a gate insulating layer 23X formed on the semiconductor substrate 40, and the gate electrode 23G formed on the gate insulating layer 23X. The impurity region 21S is connected in series between the amplifier transistor 21 and the address transistor 23.

The photoelectric conversion unit 10A mentioned earlier is arranged on the interlayer insulating layer 50. In other words, in the present embodiment, the pixels 24 constituting the pixel array PA are formed on the semiconductor substrate 40. The pixels 24 arranged in two dimensions on the semiconductor substrate 40 form a photosensitive region. The distance (i.e., the pixel pitch) between two connected pixels 24 may be, for example, about 2 μm.

The photoelectric conversion unit 10A has the structure of the photoelectric conversion element 10 mentioned earlier.

A color filter 60 is formed on the photoelectric conversion unit 10A, and a microlens 61 is formed on the color filter 60. The color filter 60 is formed, for example, as an on-chip color filter by patterning, and a photosensitive resin or the like in which a dye or pigment is dispersed is used. The microlens 61 is formed, for example, as an on-chip microlens, and an ultraviolet photosensitive material or the like is used.

The imaging device 100 can be manufactured using a general semiconductor manufacturing process. In particular, in the case of using a silicon substrate as the semiconductor substrate 40, the imaging device 100 can be manufactured by utilizing various silicon semiconductor processes.

The imaging device 100 may operate in a rolling shutter mode, where the pixels 24 are sequentially exposed and their signals are read out on a pixel-row-by-pixel-row basis, for example, or may operate in a global shutter mode, where the exposure period of the pixels 24 is unified. When the imaging device 100 operates in a rolling shutter mode, at the time of imaging, for example, the voltage supply circuitry 19 continues supplying a voltage to the upper electrode 6 that causes the photoelectric conversion unit 10A to become sensitive, and the readout operation of the signal charge is performed sequentially on a pixel-row-by-pixel-row basis. When the imaging device 100 operates in a global shutter mode, the voltage supply circuitry 19 supplies a voltage to the upper electrode 6 for imaging at low or high sensitivity during the exposure period, and supplies a voltage to the upper electrode 6 for preventing the photoelectric conversion unit 10A from becoming sensitive during the non-exposure period. During this non-exposure period, a signal charge readout operation is performed sequentially on a pixel-row-by-pixel-row basis. Note that the readout operation of the imaging device 100 is not limited to such an operation, and the readout operation of known imaging devices may be applied.

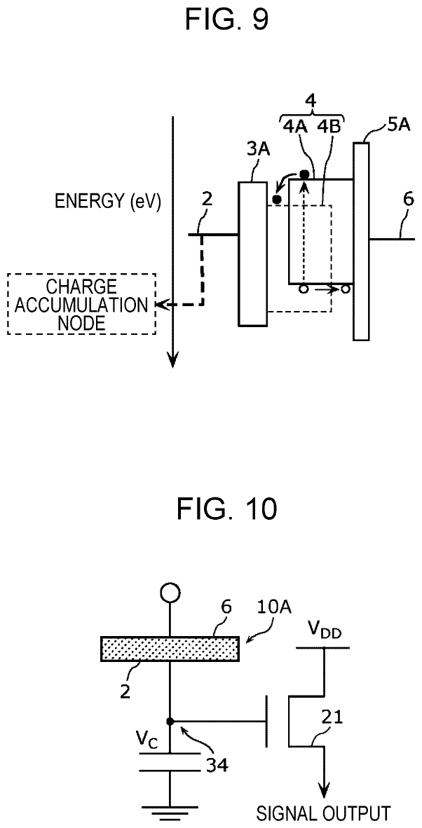

Note that the signal charge detected by the imaging device 100 may comprise electrons. In this case, the charge accumulation node 34, which is electrically connected to the lower electrode 2, accumulates electrons. FIG. 9 is an exemplary energy band diagram of another photoelectric conversion element according to the present embodiment. In FIG. 9, the energy band of each layer is depicted as a rectangle. Also, in FIG. 9, electrons are depicted as black circles and holes as white circles, illustrating schematically some of the movements of electrons and holes. Although the energy band of the donor semiconductor material 4A and the energy band of the acceptor semiconductor material 4B are illustrated in FIG. 9 as being shifted laterally, this is for the sake of clarity and does not imply that the donor semiconductor material 4A and the acceptor semiconductor material 4B are distributed separately in the thickness direction of the photoelectric conversion layer 4. Additionally, the energy band of the acceptor semiconductor material 4B is depicted as a dashed-line rectangle; this is again for the sake of clarity and is not intended to be distinguished from a solid-line rectangle.

FIG. 9 illustrates, as another example of the photoelectric conversion element in the imaging device according to the present embodiment, the energy bands of a photoelectric conversion element including a charge blocking layer 3A and a charge blocking layer 5A instead of the charge blocking layer 3 and the charge blocking layer 5 in the photoelectric conversion element 10 mentioned earlier. The charge blocking layer 5A is an example of a first charge blocking layer, and the charge blocking layer 3A is an example of a second charge blocking layer.

The charge blocking layer 3A is configured to block charge of polarity opposite to that of the signal charge. As illustrated in FIG. 9, the ionization potential of the charge blocking layer 3A is, for example, less than or equal to the ionization potential of the donor semiconductor material 4A of the photoelectric conversion layer 4. The charge blocking layer 3A suppresses the injection of charge (specifically, holes) with polarity opposite to that of the signal charge from the lower electrode 2 to the photoelectric conversion layer 4. This makes it possible to reduce spurious signals that adversely affect the SN ratio.

In addition, the charge blocking layer 5A is configured to block charge of polarity opposite to that of the signal charge. The ionization potential of the charge blocking layer 5A is greater than the ionization potential of the donor semiconductor material 4A. Additionally, the ionization potential of the charge blocking layer 5A may be at least 1 eV greater than the ionization potential of the donor semiconductor material 4A.

By providing the charge blocking layer 5A having an ionization potential that is greater than the ionization potential of the donor semiconductor material 4A as mentioned earlier, holes generated in the photoelectric conversion layer 4 can be accumulated at the interface between the photoelectric conversion layer 4 and the charge blocking layer 5A. In particular, if the ionization potential of the charge blocking layer 5A is at least 1 eV greater than the ionization potential of the donor semiconductor material 4A, holes generated in the photoelectric conversion layer 4 are easily accumulated at the interface between the photoelectric conversion layer 4 and the charge blocking layer 5A.

Additionally, the electron affinity of the charge blocking layer 5A is greater than or equal to the electron affinity of the acceptor semiconductor material 4B. Accordingly, the charge blocking layer 5A suppresses the injection of the signal charge (specifically, electrons) from the upper electrode 6 to the photoelectric conversion layer 4. This makes it possible to reduce spurious signals caused by dark current, which adversely affect the SN ratio.

The thickness of the charge blocking layer 3A and the charge blocking layer 5A is, for example, the same as the charge blocking layer 3 and the charge blocking layer 5 mentioned earlier. Additionally, the transmittance of light in the visible light range of the charge blocking layer 5A is, for example, the same as that of the charge blocking layer 5 mentioned earlier.

### Operation of Imaging Device

The operation of the imaging device 100 will now be described with reference to FIGS. 5 and 10. Here, the case where holes are used as the signal charge will be described.

FIG. 10 is a diagram illustrating a portion of a schematic circuit configuration of each pixel 24 according to the present embodiment. In FIG. 10, for simplicity of illustration, the charge accumulation node 34 is grounded via a capacitor, and some of the components included in the pixel 24 are depicted. Additionally, the case will be described in which a voltage Vc of the charge accumulation node 34 is reset to a reference voltage Vref in the initial state before exposure. The reference voltage Vref is, for example, 0 V, but is not particularly limited as long as it is a voltage at which holes can be accumulated in the charge accumulation node 34.

First, the operation during normal exposure (high-sensitivity imaging) will be described. During normal exposure, the voltage supply circuitry 19 applies a voltage V2 to the upper electrode 6 such that, for example, a bias voltage Vo becomes higher than the second voltage range described using FIG. 5 and the photocurrent density substantially remains unchanged. In the initial state, since the bias voltage Vo=V2−Vref, when the reference voltage Vref is 0 V, the voltage V2 is higher than the second voltage range and is a voltage at which the photocurrent density substantially remains unchanged. For example, when the photoelectric conversion layer 4 is composed of an organic material, the voltage V2 is about 10 V.

When the photoelectric conversion unit 10A of each pixel 24 is irradiated with light in this state, pairs of holes and electrons are generated by photoelectric conversion according to the amount of light incident on the photoelectric conversion unit 10A. The generated holes move to the lower electrode 2 due to the potential difference between the upper electrode 6 and the lower electrode 2 and accumulate in the charge accumulation node 34. This causes the voltage Vc of the charge accumulation node 34 to increase from the reference voltage Vref. Because the amount of incident light is different for each pixel 24, the value of the voltage Vc is also different for each pixel 24. Also, because pairs of holes and electrons are not generated in pixels 24 where no light enters, the voltage Vc remains as it is as the reference voltage Vref. Since the bias voltage Vo=V2−Vc, the bias voltage Vo applied to the photoelectric conversion unit 10A is different for each pixel 24. However, during normal exposure, the voltage V2 is higher than the second voltage range, and since the photocurrent density hardly changes with respect to voltage, even if the bias voltage Vo is different, there is only a small impact on the photocurrent density.

Next, the operation during exposure in a state where the light is electrically reduced (low-sensitivity imaging) will be described. During exposure in a state where the light is electrically reduced, the voltage supply circuitry 19 applies a voltage V1 to the upper electrode 6 such that, for example, the bias voltage Vo becomes a voltage within the first voltage range described using FIG. 5. In the initial state before exposure, since the bias voltage Vo=V1−Vref, if the reference voltage Vref is 0 V, the voltage V1 is a voltage within the first voltage range. Also in this case, as under normal exposure, holes accumulate in the charge accumulation node 34 according to the amount of incident light, and the value of the voltage Vc of the charge accumulation node 34 is different for each pixel 24. That is, since the bias voltage Vo=V1−Vc, the bias voltage Vo applied to the photoelectric conversion unit 10A will be different for each pixel 24. In the present embodiment, because the characteristics represent that the change in photocurrent density with respect to voltage is small in the first voltage range, even if the bias voltage Vo is different for each pixel 24, the variations in photocurrent density are small. That is, it means that the degradation of linearity characteristics of the output with respect to the amount of incident light in the imaging device 100 is small.

In addition, when the bias voltage Vo applied to the photoelectric conversion unit 10A becomes 0 V, photocurrent is no longer generated. That is, since the bias voltage Vo=V1−Vc, the state where V1=Vc represents the saturated signal amount for the imaging device 100. In the present embodiment, since the width of the first voltage range is greater than or equal to 0.5 V, setting a voltage near the upper limit of the first voltage range as the voltage V1 allows the imaging device 100 to have a sufficient saturated signal amount. Variations in the value of the voltage Vc that fall within the first voltage range correspond to the width of the dynamic range. For example, if the width of the first voltage range is greater than or equal to 0.5 V, an imaging device with a conversion gain of 50 μV/e—can achieve a dynamic range greater than or equal to 80 dB, which corresponds to the human eye.

After the exposure, a signal according to the amount of holes accumulated in the charge accumulation node 34 is read out by the charge detection circuit 35 including the amplifier transistor 21.

In contrast, if the photoelectric conversion unit has photocurrent characteristics as illustrated in FIG. 6, since the characteristics do not have the first voltage range mentioned earlier, it is not possible to suppress the degradation of linearity characteristics of the output with respect to the amount of incident light during exposure in a state where the light is electrically reduced, and a sufficient saturated signal amount cannot be achieved. In contrast, in the imaging device 100 according to the present embodiment, since the photoelectric conversion unit 10A has the photocurrent characteristics having the first voltage range as mentioned earlier, when imaging with adjusted sensitivity, even in low-sensitivity imaging, it is possible to suppress the degradation of linearity characteristics of the output with respect to the amount of incident light, and also to maintain a sufficient saturated signal amount.

Although the operation of the aforementioned imaging device 100 involves adjusting the sensitivity by controlling the bias voltage Vo through the voltage supply circuitry 19 applying a voltage to the upper electrode 6, this is not the only possible operation. For example, the imaging device 100 may include, instead of the voltage supply circuitry 19, voltage supply circuitry capable of changing the magnitude of the reference voltage Vref. It is permissible to control the bias voltage Vo by keeping the voltage applied to the upper electrode 6 unchanged, while allowing the aforementioned voltage supply circuitry to change the reference voltage Vref to different voltages during low-sensitivity imaging and high-sensitivity imaging.

### EXAMPLES

Hereinafter, the photoelectric conversion element provided in the imaging device according to the present disclosure will be described using an example. However, the present disclosure is not limited in any way only to the following example. In detail, a photoelectric conversion element provided in an imaging device according to an embodiment of the present disclosure, and a photoelectric conversion element for characteristic comparison were fabricated, and current-voltage characteristics were measured.

### Fabrication of Photoelectric Conversion Elements

Photoelectric conversion elements in an example and a comparative example were fabricated.

### First Example

As a supporting substrate, a substrate coated with TiN was used. A second charge blocking layer was formed by using TiN with a work function of 4.7 eV as a lower electrode and depositing 9,9′-[1,1′-Biphenyl]-4,4′-diylbis[3,6-bis(1,1-dimethyl ethyl)]-9H-carbazole onto the lower electrode via vacuum deposition. The film thickness of the second charge blocking layer obtained at this time was 50 nm.

Next, on the second charge blocking layer, subphthalocyanine, which is a donor semiconductor material, and fullerene C60, which is an acceptor semiconductor material, were co-deposited by vacuum deposition as materials for the photoelectric conversion layer, thereby forming the photoelectric conversion layer. The weight ratio between the donor semiconductor material and the acceptor semiconductor material was 1:3. Also, the film thickness of the photoelectric conversion layer obtained at this time was about 500 nm. Furthermore, as subphthalocyanine, a subphthalocyanine with boron (B) as the central metal, coordinated with chloride ions as ligands, was used.

Next, a first charge blocking layer was formed by depositing 1,3-Bis(3-(diphenylphosphoryl)phenyl)benzene, as a material for the first charge blocking layer, to a thickness of 5 nm via vacuum deposition through a metal shadow mask onto the photoelectric conversion layer.

Next, an ITO film was formed, as an upper electrode, with a thickness of 30 nm by sputtering on the first charge blocking layer. Subsequently, an Al₂O₃ film was deposited, as a sealing layer, on the upper electrode through atomic layer deposition, thereby obtaining a photoelectric conversion element.

### First Comparative Example

A photoelectric conversion element was obtained through the same process as that in the first example, except that the first charge blocking layer was not formed, and the upper electrode was directly formed on the photoelectric conversion layer.

### Measurement of Ionization Potential and Electron Affinity of Materials

The ionization potential and electron affinity were measured for each material used in the first example and the first comparative example.

In the measurement of ionization potential, samples of each material used in the first example and the first comparative example were prepared by depositing them on a glass substrate coated with ITO. Next, using an atmospheric photoelectron spectrometer (AC-3, manufactured by Riken Keiki), the number of photoelectrons were measured when the energy of ultraviolet radiation was changed. The energy position where photoelectrons begin to be detected was determined as the ionization potential.

In the measurement of electron affinity, samples of each material used in the first example and the first comparative example were first prepared on a quartz substrate. Next, for the prepared samples, the absorption spectrum was measured using a spectrophotometer (U4100, manufactured by Hitachi High-Tech Corporation). The optical band gap was calculated from the result of the absorption edge of the obtained absorption spectrum. The electron affinity was estimated through subtraction of the ionization potential obtained from the above-mentioned measurement of ionization potential and the calculated optical band gap.

Table 1 indicates the ionization potential and electron affinity of each material used in the first example and the first comparative example.

TABLE 1

| | | | Ionization | Electron |
|---|---|---|---|---|
| | | | potential | affinity |
| Layer | | Material | [eV] | [eV] |
| Second charge blocking layer | | 9,9′-[1,1′-Biphenyl]-4,4′-diylbis[3,6- | 5.8 | 2.7 |
| | | bis(1,1-dimethyl ethyl)]-9H-carbazole | | |
| Photoelectric | Acceptor | C60 fullerene | 6.2 | 4.2 |
| conversion | semiconductor | | | |
| layer | material | | | |
| | Donor | subphthalocyanine | 5.5 | 3.4 |
| | semiconductor | | | |
| | material | | | |

| First charge blocking layer | 1,3-Bis(3- | 6.9 | 2.8 |
|---|---|---|---|
| | (diphenylphosphoryl)phenyl)benzene | | |

As indicated in Table 1, in the photoelectric conversion element of the first example, the electron affinity of the first charge blocking layer is less than the electron affinity of the acceptor semiconductor material; more specifically, it is at least 1 eV less than the electron affinity of the acceptor semiconductor material.

### Measurement of Current-Voltage Characteristics

The current density in light and dark conditions was measured for the photoelectric conversion elements in the first example and the first comparative example. A semiconductor device parameter analyzer (B1500A, manufactured by Keysight Technologies, Inc.) was used to measure the current density. Specifically, the bias voltage (potential difference ΔV) applied between the pair of electrodes of the photoelectric conversion element, that is, between the upper electrode and the lower electrode, was varied to measure the current-voltage characteristics in light and dark conditions. Additionally, the bias voltage was applied such that the potential of the upper electrode would become higher than the potential of the lower electrode. The irradiation intensity of light in a light condition was set to 1000 lux.

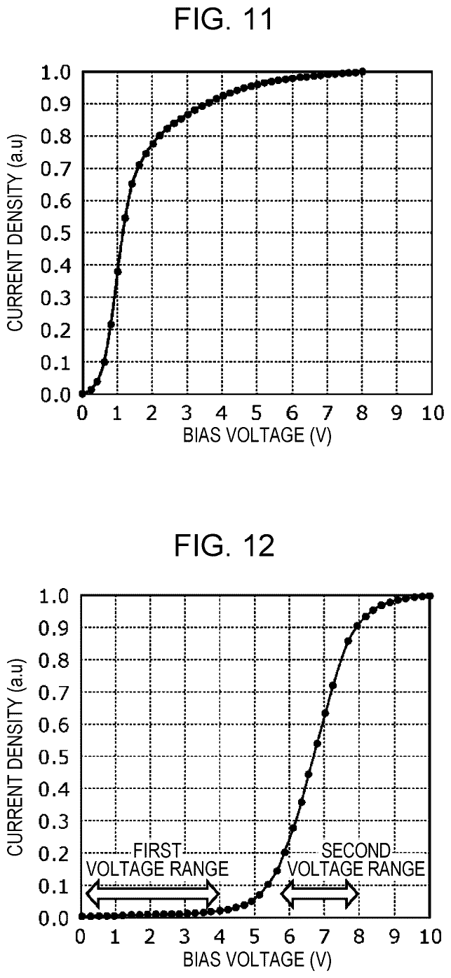

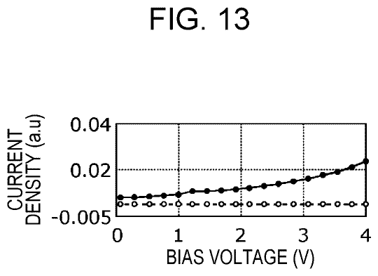

FIG. 11 illustrates the current-voltage characteristics in a light condition when the bias voltage is applied to the photoelectric conversion element in the first comparative example. Additionally, FIG. 12 illustrates the current-voltage characteristics in a light condition when the bias voltage is applied to the photoelectric conversion element in the first example. Furthermore, FIG. 13 illustrates the current-voltage characteristics in light and dark conditions when the bias voltage is applied to the photoelectric conversion element in the first example. Note that FIG. 13 illustrates the current-voltage characteristics of the photoelectric conversion element in the first example in the vicinity of the first voltage range.

In FIGS. 11 to 13, the vertical axis indicates the current density in normalized absolute values, and the horizontal axis indicates the potential difference ΔV (bias voltage) between the first electrode and the second electrode. Moreover, in FIGS. 11 to 13, the current density is illustrated in normalized arbitrary units, with the photocurrent density value set to 1 when the photocurrent density saturates as the bias voltage is increased. Specifically, FIG. 11 depicts the current density normalized with the photocurrent density value set to 1 when the potential difference ΔV is 8 V in the photoelectric conversion element in the first comparative example. Additionally, FIGS. 12 and 13 depict the current density normalized with the photocurrent density value set to 1 when the potential difference ΔV is 10 V in the photoelectric conversion element in the first example. Also, in FIG. 13, a black-circle plot indicates the current-voltage characteristics under light irradiation, whereas a white-circle plot indicates the current-voltage characteristics under no light irradiation.

As illustrated in FIG. 11, in the photoelectric conversion element of the first comparative example, where a first charge blocking layer is not provided, the photocurrent density sharply increases from around 0 V. This is thought to be because the photoelectric conversion element in the first comparative example is not provided with a first charge blocking layer, allowing electrons generated in the photoelectric conversion layer to be collected by the upper electrode even at low bias voltages.

In contrast, as illustrated in FIGS. 12 and 13, in the photoelectric conversion element in the first example, where the first charge blocking layer is provided, the increase in photocurrent density is small until around 5 V bias voltage. As such, in the photocurrent characteristics of the photoelectric conversion element in the first example, the first voltage range where the ratio of change in photocurrent density with respect to voltage is small spreads over 0.5 V or more, as opposed to the second voltage range where the photocurrent density increases sharply. This is thought to be because the photoelectric conversion element in the first example includes the first blocking layer with an electron affinity smaller than that of the acceptor semiconductor material. At relatively low bias voltages, electrons accumulate at the interface between the photoelectric conversion layer and the first charge blocking layer, making it difficult for photocurrent to flow due to effects such as electric field relaxation.

Additionally, in FIG. 13, an example of the I-V characteristics of the photoelectric conversion element in the first example, when a voltage is applied between the upper electrode and the lower electrode under no light irradiation, is also indicated by dashed lines. That is, the current density in the graph indicated by dashed lines represents the dark current density corresponding to the current flowing when the photoelectric conversion element in the first example is not irradiated with light. As illustrated in FIG. 13, in the photocurrent characteristics of the photoelectric conversion element in the first example, the photocurrent density in the first voltage range is greater than the dark current density.

Accordingly, the photoelectric conversion element in the first example has photocurrent characteristics having the first voltage range and the second voltage range. Therefore, the photoelectric conversion element in the first example can perform imaging using bias voltages in the first voltage range.

Although the photoelectric conversion element and the imaging device according to the present disclosure have been described above based on the embodiment and the example, the present disclosure is not limited to the embodiment and the example. Various modifications conceived by those skilled in the art, implemented in the embodiment and the example, as long as they do not depart from the gist of the present disclosure, as well as other embodiments constructed by combining some components in the embodiment and the example, are within the scope of the present disclosure.

### Supplementary 1

Modifications of the embodiment of the present disclosure may include, but are not limited to, the following.

A photoelectric conversion element including:
a photoelectric conversion layer that converts light into signal charge;
a first electrode that collects the signal charge;
a second electrode, the photoelectric conversion layer being provided between the first electrode and the second electrode; and
a first charge blocking layer, located between the photoelectric conversion layer and the second electrode, containing a first charge blocking material,
wherein the first charge blocking layer is configured to block charge of polarity opposite to that of the signal charge,
a photocurrent characteristic of the photoelectric conversion element, with respect to a voltage applied between the first electrode and the second electrode in a case where the photoelectric conversion layer is irradiated with light having certain illuminance, exhibits a first voltage range and a second voltage range,
a first photocurrent density corresponding to a first voltage included in the first voltage range is less than a second photocurrent density corresponding to a second voltage included in the second voltage range,
the first voltage is less than the second voltage,
a ratio of a difference between photocurrent densities corresponding to first voltages included in the first voltage range to a difference between the first voltages is less than a ratio of a difference between photocurrent densities corresponding to second voltages included in the second voltage range to a difference between the second voltages; and
an absolute value of a difference between a maximum voltage of the first voltage range and a minimum voltage of the first voltage range is greater than or equal to 0.5 V.

The first voltage range may be continuous. The second voltage range may be continuous. The first voltage may be the maximum voltage of the first voltage range. The second voltage may be a minimum voltage of the second voltage range.

A photoelectric conversion element and an imaging device according to the present disclosure can be applied to various camera systems and sensor systems, such as medical cameras, surveillance cameras, in-vehicle cameras, ranging cameras, microscope cameras, drone cameras, and robot cameras.

What is claimed is:

1. A photoelectric conversion element comprising:
a photoelectric conversion layer that converts light into signal charge;
a first electrode that collects the signal charge;
a second electrode that faces the first electrode via the photoelectric conversion layer; and
a first charge blocking layer, located between the photoelectric conversion layer and the second electrode, containing a first charge blocking material,
wherein the first charge blocking layer is configured to block movement of charge of polarity opposite to that of the signal charge from the photoelectric conversion layer to the second electrode,
a photocurrent characteristic of the photoelectric conversion element, with respect to a voltage applied between the first electrode and the second electrode in a case where the photoelectric conversion layer is irradiated with light having certain illuminance, exhibits a first voltage range and a second voltage range,
a first photocurrent density at a first voltage included in the first voltage range is less than a second photocurrent density at a second voltage included in the second voltage range,
the first voltage is less than the second voltage,
a ratio of change in photocurrent density at the first voltage is less than a ratio of change in photocurrent density at the second voltage, and
an absolute value of a difference between a maximum voltage of the first voltage range and a minimum voltage of the first voltage range is greater than or equal to 0.5 V.

2. A photoelectric conversion element comprising:
a photoelectric conversion layer that converts light into signal charge;
a first electrode that collects the signal charge;
a second electrode that faces the first electrode via the photoelectric conversion layer; and
a first charge blocking layer, located between the photoelectric conversion layer and the second electrode, containing a first charge blocking material,
wherein the photoelectric conversion layer contains a donor material and an acceptor material,
the signal charge comprises holes,
an electron affinity of the first charge blocking material is at least 1 eV less than an electron affinity of the acceptor material,
a photocurrent characteristic of the photoelectric conversion element, with respect to a voltage applied between the first electrode and the second electrode in a case where the photoelectric conversion layer is irradiated with light having certain illuminance, exhibits a first voltage range and a second voltage range,
a first photocurrent density at a first voltage included in the first voltage range is less than a second photocurrent density at a second voltage included in the second voltage range,
the first voltage is less than the second voltage,
a ratio of change in photocurrent density at the first voltage is less than a ratio of change in photocurrent density at the second voltage, and
an absolute value of a difference between a maximum voltage of the first voltage range and a minimum voltage of the first voltage range is greater than or equal to 0.5 V.

3. A photoelectric conversion element comprising:
a photoelectric conversion layer that converts light into signal charge;
a first electrode that collects the signal charge;
a second electrode that faces the first electrode via the photoelectric conversion layer; and
a first charge blocking layer, located between the photoelectric conversion layer and the second electrode, containing a first charge blocking material,
wherein the photoelectric conversion layer contains a donor material and an acceptor material,
the signal charge comprises electrons;
an ionization potential of the first charge blocking material is at least 1 eV greater than an ionization potential of the donor material,
a photocurrent characteristic of the photoelectric conversion element, with respect to a voltage applied between the first electrode and the second electrode in a case where the photoelectric conversion layer is irradiated with light having certain illuminance, exhibits a first voltage range and a second voltage range,
a first photocurrent density at a first voltage included in the first voltage range is less than a second photocurrent density at a second voltage included in the second voltage range,
the first voltage is less than the second voltage,
a ratio of change in photocurrent density at the first voltage is less than a ratio of change in photocurrent density at the second voltage, and
an absolute value of a difference between a maximum voltage of the first voltage range and a minimum voltage of the first voltage range is greater than or equal to 0.5 V.

4. The photoelectric conversion element according to claim 1, wherein:
in the photocurrent characteristic, a maximum value of the photocurrent density in the first voltage range is less than or equal to 10% of a maximum value of the photocurrent density in the second voltage range.

5. The photoelectric conversion element according to claim 1, wherein:
in the photocurrent characteristic, a maximum value of the photocurrent density in the first voltage range is less than or equal to 10% of a photocurrent density value when the photocurrent density saturates as the voltage is increased.

6. The photoelectric conversion element according to claim 1, wherein:
in the photocurrent characteristic, an amount of change in photocurrent density per 0.5 V in the first voltage range is less than or equal to 3% of a photocurrent density value when the photocurrent density saturates as the voltage is increased.

7. The photoelectric conversion element according to claim 1, wherein:
in the photocurrent characteristic, magnitude of a ratio of change in photocurrent density at a voltage in the first voltage range is less than or equal to 20% of magnitude of a ratio of change in photocurrent density at a voltage in the second voltage range.

8. The photoelectric conversion element according to claim 1, wherein:
a thickness of the first charge blocking layer is less than or equal to 50 nm.

9. The photoelectric conversion element according to claim 1, further comprising:
a second charge blocking layer located between the photoelectric conversion layer and the first electrode,
wherein the second charge blocking layer is configured to block charge of polarity opposite to that of the signal charge.

10. The photoelectric conversion element according to claim 9, wherein:
a thickness of the first charge blocking layer is less than a thickness of the second charge blocking layer.

11. The photoelectric conversion element according to claim 1, wherein:
when the voltage applied between the first electrode and the second electrode is increased from 0 V, the photocurrent characteristic has a first inflection point that occurs because the photocurrent density changes sharply, and a second inflection point at a higher voltage than a voltage at the first inflection point; and
the first voltage range is included in a voltage range between 0 V and the voltage at the first inflection point, and the second voltage range is included in a voltage range between the voltage at the first inflection point and the voltage at the second inflection point.

12. The photoelectric conversion element according to claim 1, wherein the first voltage is the maximum voltage of the first voltage range, and the second voltage is a minimum voltage of the second voltage range.

13. The photoelectric conversion element according to claim 1, wherein the minimum voltage of the first voltage range is 0 V.

14. The photoelectric conversion element according to claim 1, wherein an absolute value of a difference between the maximum voltage and the minimum voltage is greater than or equal to 1 V.

15. The photoelectric conversion element according to claim 1, wherein an absolute value of a difference between the maximum voltage and the minimum voltage is greater than or equal to 2 V.

16. The photoelectric conversion element according to claim 1, wherein an absolute value of a difference between the maximum voltage and the minimum voltage is less than or equal to 5 V.

17. The photoelectric conversion element according to claim 1, wherein an absolute value of a difference between the maximum voltage and the minimum voltage is less than or equal to 4 V.

18. The photoelectric conversion element according to claim 1, wherein:
a ratio of change in photocurrent density at the first voltage is less than or equal to 20% of a ratio of change in photocurrent density at the second voltage.

19. An imaging device comprising:
the photoelectric conversion element according to claim 1;
a charge detection circuit connected to the first electrode; and
voltage supply circuitry that provides a potential difference between the first electrode and the second electrode.
